(19) United States
(12) Patent Application Publication
(10) Pub. No.: US 2020/0328264 A1
(43) Pub. Date: Oct. 15, 2020

(54) OLED SUBSTRATE, MANUFACTURING METHOD THEREOF AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Yihao WU, Beijing (CN); Yanxia XIN, Beijing (CN); Mingyin YU, Beijing (CN); Zheng BAO, Beijing (CN); Bo LI, Beijing (CN); Xueping LI, Beijing (CN)

(21) Appl. No.: 16/755,746

(22) PCT Filed: May 20, 2019
(86) PCT No.: PCT/CN2019/087573

§ 371 Date: Apr. 13, 2020

(30) Foreign Application Priority Data
May 21, 2018 (CN) 201810490766.0

(51) Int. Cl. H01L 27/32; H01L 51/00; H01L 51/56

(52) U.S. Cl. CPC H01L 27/3246; H01L 51/0097; H01L 2227/323; H01L 27/3276; H01L 51/56

(57) ABSTRACT

Embodiments of the present disclosure disclose an OLED substrate, a manufacturing thereof and a display device. The OLED substrate includes a base substrate, a patterned metal wiring formed on a surface of the base substrate, a flatness adjustment layer formed on a surface of the base substrate not covered by the patterned metal wiring, a planarization layer formed on a surface of the flatness adjustment layer facing away from the base substrate and on a surface of the patterned metal wiring facing away from the base substrate, and an OLED anode formed on a surface of the planarization layer facing away from the base substrate.

### TECHNICAL FIELD

The present disclosure relates to the field of display technologies, and in particular to an OLED substrate, a manufacturing method thereof and a display device.

### BACKGROUND ART

Active-matrix organic light emitting diode (AMOLED) panels are widely applied in the field of display thanks to their high brightness, full angle of view, fast response speed, flexible display and so on.

At present, during the manufacture of a small-sized AMOLED panel, a fine metal mask (FFM) process is often used for manufacturing metal wiring on a low temperature poly-silicon (LTPS) backplate of the AMOLED panel. However, for an AMOLED panel which is manufactured by using the FFM process and has been used for a long term, images displayed by the AMOLED panel are prone to color cast, e.g., reddishness, which leads to a poor display effect of the AMOLED panel.

### SUMMARY

It is an objective of the embodiments of the present disclosure to provide an OLED substrate, a manufacturing method thereof and a display device so as to improve the OLED color cast of OLED display devices.

In a first aspect of the embodiments of the present disclosure, an OLED substrate is provided, comprising: a base substrate; a patterned metal wiring formed on a surface of the base substrate; a flatness adjustment layer formed on a surface of the base substrate not covered by the metal wiring; a planarization layer formed on a surface of the flatness adjustment layer facing away from the base substrate and on a surface of the metal wiring facing away from the base substrate; and an OLED anode formed on a surface of the planarization layer facing away from the base substrate.

In one embodiment, the metal wiring and the flatness adjustment layer are formed by a same mask plate respectively.

In one embodiment, the OLED substrate further comprises: a pixel defining layer formed on the surface of the planarization layer facing away from the base substrate, wherein a pixel hole is provided in a region of the pixel defining layer corresponding to the OLED anode, and an orthogonal projection of the flatness adjustment layer on the base substrate at least covers that of the pixel hole on the base substrate.

In one embodiment, in a region of the base substrate to which the pixel hole is orthogonally projected, the surface of the flatness adjustment layer facing away from the base substrate is at the same height level as the surface of the metal wiring facing away from the base substrate in this region.

In one embodiment, the base substrate comprises a flexible backplate, and a buffer layer, an active layer, a gate insulating layer, a gate and an interlayer dielectric layer sequentially formed in a stack on the flexible backplate, and the metal wiring is formed on a surface of the interlayer dielectric layer facing away from the gate.

In one embodiment, one part of the metal wiring is electrically connected to the active layer to form a source and a drain of a thin film transistor, and the OLED anode is electrically connected to the drain of the thin film transistor, and another part of the metal wiring is electrically connected to the gate to form a signal line of a compensation circuit.

According to the OLED substrate provided in the embodiments of the present disclosure, a flatness adjustment layer is formed on a surface of the base substrate not covered by the metal wiring such that the flatness of the plane in which the metal wiring is located can be adjusted by using the flatness adjustment layer, thereby ensuring a high flatness of the planarization layer formed on the surface of the flatness adjustment layer facing away from the base substrate and on the surface of the metal wiring facing away from the base substrate, and in turn ensuring a high flatness of the OLED anode formed on the surface of the planarization layer facing away from the base substrate. In other words, the OLED anode in the OLED substrate provided in the embodiments of the present disclosure will not appear uneven due to the presence of the metal wiring at its bottom. Therefore, each pixel of the OLED substrate provided in the embodiments of the present disclosure will not be confronted by the problem of uneven or asymmetrical pixel light brightness caused by unevenness of the corresponding OLED anode. In this way, after RGB color mixing of the pixels on the OLED substrate, the OLED substrate will not be subjected to OLED color cast because of uneven or asymmetrical pixel light brightness of a certain pixel. Therefore, the OLED substrate provided in the embodiments of the present disclosure can effectively improve the OLED color cast of an OLED display device in which it is located, and thus ensure the display effect of the OLED device.

In a second aspect of the embodiments of the present disclosure, a manufacturing method for an OLED substrate is provided, comprising: providing a base substrate; forming a patterned metal wiring on a surface of the base substrate; forming a flatness adjustment layer on a surface of the base substrate not covered by the metal wiring; forming a planarization layer on a surface of the flatness adjustment layer facing away from the base substrate and on a surface of the metal wiring facing away from the base substrate; and forming an OLED anode on a surface of the planarization layer facing away from the base substrate.

In one embodiment, the step of forming a patterned metal wiring on a surface of the base substrate comprises: depositing a metal layer on a surface of the base substrate; applying a photoresist on a surface of the metal layer facing away from the base substrate, and exposing and developing the photoresist by using a mask plate; and etching the metal layer to form the patterned metal wiring, and the step of forming a flatness adjustment layer on a surface of the base substrate not covered by the metal wiring comprises: depositing a flatness adjustment dielectric on a surface of the base substrate not covered by the metal wiring and on a surface of the metal wiring facing away from the base substrate; applying a photoresist on a surface of the flatness adjustment dielectric facing away from the base substrate, and reversely exposing and developing the photoresist by using a same mask plate as the one used in the formation of the metal wiring; and etching the flatness adjustment dielectric to form the flatness adjustment layer.

In one embodiment, the manufacturing method for an OLED substrate further comprises: forming a pixel defining layer on the surface of the planarization layer facing away from the base substrate and on the surface of the OLED anode facing away from the base substrate; and forming a pixel hole corresponding to the OLED anode in the pixel defining layer, wherein an orthogonal projection of the flatness adjustment layer on the base substrate at least covers that of the pixel hole on the base substrate.

The manufacturing method for an OLED substrate provided in the embodiments of the present disclosure can achieve the same beneficial effects as the OLED substrate provided in the above technical solutions, which will not be repeated for simplicity.

In a third aspect of the embodiments of the present disclosure, a display device is provided, the display device comprising the OLED substrate provided in the above technical solutions. The display device provided in the embodiments of the present disclosure can achieve the same beneficial effects as the OLED substrate provided in the above technical solutions, which will not be repeated for simplicity.

### BRIEF DESCRIPTION OF DRAWINGS

The drawings described herein are used for providing further understanding of the embodiments of the present disclosure and constitute part of the embodiments of the present disclosure, and exemplary embodiments of the present disclosure and explanations thereof are used to explain the present disclosure rather than improperly limit the present disclosure. In the drawings:

FIG. 1 is a schematic structure view of an existing OLED substrate;

FIG. 2 is a schematic structure view of the OLED substrate provided in an embodiment of the present disclosure;

FIG. 3 is a flow chart showing the manufacturing method for an OLED substrate provided in an embodiment of the present disclosure;

FIG. 4 is a flow chart showing the manufacturing method for an OLED substrate provided in an embodiment of the present disclosure.

### DETAILED DESCRIPTION OF EMBODIMENTS

In order to further explain the OLED substrate, the manufacturing method thereof and the display device provided in the embodiments of the present disclosure, detailed description will be given below with reference to the drawings of the specification.

Referring to FIG. 1, the existing OLED substrate comprises a base substrate 1 and a metal wiring 2 formed on a surface of the base substrate 1 by using an FFM process; a planarization layer 4 formed on a surface of the base substrate 1 not covered by the metal wiring 2 and on a surface of the metal wiring 2 facing away from the base substrate 1; and an OLED anode 5 and a pixel defining layer 6 formed on a surface of the planarization layer 4 facing away from the base substrate 1, wherein a pixel hole A is provided in a region of the pixel defining layer 6 corresponding to the OLED anode 5.

At the bottom of the pixel hole A in the OLED substrate, i.e., the bottom of the OLED anode 5, a patterned metal wiring 2 corresponding to a pixel compensation circuit is formed, and this part of the metal wiring 2 has a certain thickness, so the planarization layer 4 covering this part of metal wiring 2 and the OLED anode 5 formed on the surface of the planarization layer 4 both have a thin thickness. This can easily cause unevenness at the bottom of the pixel hole A, e.g., an arc-shaped convex, which leads to unevenness or asymmetry of the pixel light brightness of the pixel hole A. Exemplarily, continuously referring to FIG. 1, the pixel in the pixel hole A is an R pixel, and the surface of the OLED anode 5 on the left of the pixel A is flat while the surface on the right is an arc-shaped convex. When an OLED light emitting unit emits light, the pixel light brightness on the left of the R pixel inside the pixel hole A is apt to be higher than the pixel light brightness on the right, which may result in uneven color mixing of the three primary colors after the pixel light of the R pixel is mixed with the pixel light of the corresponding G pixel and B pixel, and in turn give rise to reddishness of the display image, i.e., OLED color cast. Therefore, the OLED substrate is prone to OLED color cast because of unevenness at the bottom of the pixel hole, which will adversely affect the display effect of the OLED device in which the OLED substrate is located.

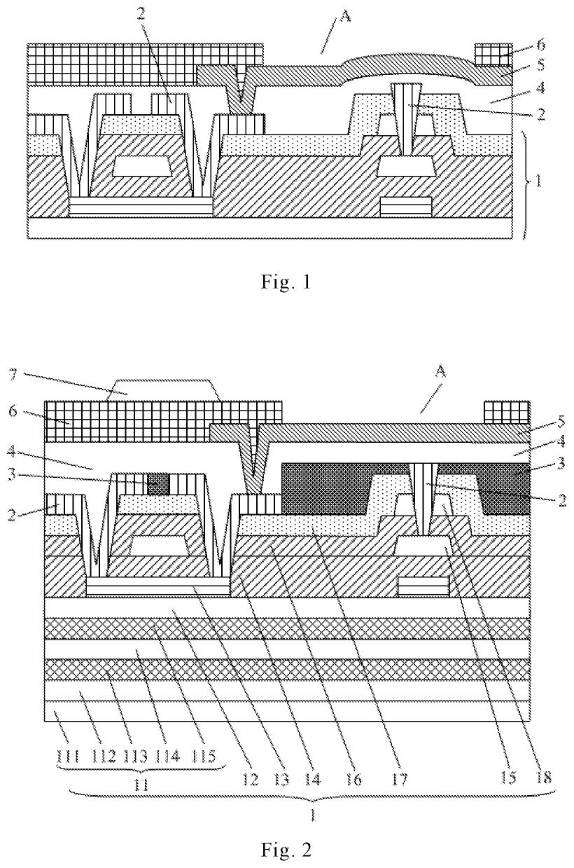

In order to effectively improve the OLED color cast of the OLED display device, the embodiments of the present disclosure provide an OLED substrate. Referring to FIG. 2, the OLED substrate comprises: a base substrate 1; a patterned metal wiring 2 formed on a surface of the base substrate 1; a flatness adjustment layer 3 formed on a surface of the base substrate 1 not covered by the metal wiring 2; a planarization layer 4 formed on a surface of the flatness adjustment layer 3 facing away from the base substrate 1 and on a surface of the metal wiring 2 facing away from the base substrate 1; and an OLED anode 5 formed on a surface of the planarization layer 4 facing away from the base substrate 1.

According to the OLED substrate provided in the embodiments of the present disclosure, a flatness adjustment layer 3 is arranged on a surface of the base substrate 1 not covered by the metal wiring 2 such that the flatness of the plane in which the metal wiring 2 is located can be adjusted by using the flatness adjustment layer 3, thereby ensuring a high flatness of the planarization layer 4 formed on the surface of the flatness adjustment layer 3 facing away from the base substrate 1 and on the surface of the metal wiring 2 facing away from the base substrate 1, and in turn ensuring a high flatness of the OLED anode 5 formed on the surface of the planarization layer 4 facing away from the base substrate 1. In other words, the OLED anode 5 in the OLED substrate provided in the embodiments of the present disclosure will not appear uneven due to the presence of the metal wiring at its bottom. Therefore, each pixel of the OLED substrate provided in the embodiments of the present disclosure will not be confronted by the problem of uneven or asymmetrical pixel light brightness caused by unevenness of the corresponding OLED anode 5. In this way, after RGB color mixing of the pixels on the OLED substrate, the OLED substrate will not be subjected to OLED color cast because of uneven or asymmetrical pixel light brightness of a certain pixel. Therefore, the OLED substrate provided in the embodiments of the present disclosure can effectively improve the OLED color cast of an OLED display device in which it is located, and thus ensure the display effect of the OLED device.

It can be understood that the structure of the base substrate 1 can often be implemented in many ways, and specifically be designed upon actual application of the OLED substrate, which will not be limited herein. Exemplarily, continuously referring to FIG. 2, in this embodiment, the base substrate 1 usually comprises a flexible backplate 11, and a buffer layer 12, an active layer 13, a gate insulating layer 14, a gate 15 and an interlayer dielectric layer 17 sequentially formed in a stack on the flexible backplate 11. The metal wiring 2 is formed on a surface of the interlayer dielectric layer 17 facing away from the gate 15. If a further metal electrode 18 such as a Ga electrode and/or a Te₂ electrode is formed between the gate 15 and the interlayer dielectric layer 17, a second gate insulating layer 16 may be further formed on a surface of the gate 15 facing away from the first gate insulating layer 14. In other words, the arrangement of the gate insulating layer is related to the arrangement of the gate and the metal electrode adjacent thereto.

Generally, the metal wiring 2 can at least be divided into two parts according to different connections with each electrode inside the base substrate 1. One part of the metal wiring 2 is electrically connected with the active layer 13 to form a source-drain of a corresponding thin film transistor, which the source-drain usually comprises a source and a drain, and the OLED anode 5 is electrically connected with the drain of the corresponding thin film transistor. Another part of the metal wiring 2 is electrically connected with the gate 15 to form a signal line of the OLED pixel compensation circuit.

The flexible backplate 11 usually comprises a transmissive base plate 111 and multiple functional thin films arranged on a surface of the base plate 111. Each functional thin film can be designed upon actual application of the OLED substrate, which will not be limited herein. Exemplarily, continuously referring to FIG. 2, in the flexible backplate 11 provided in this embodiment, a first polyimide (PI) layer 112, a water oxygen barrier layer 113, a second PI layer 114 and an alkali metal barrier layer 115 are provided sequentially in a stack on the surface of the base plate 111. The first PI layer 112 and the second PI layer 114 are used for ensuring flexibility of the flexible backplate 11, and the water oxygen barrier layer 113 is used for preventing external water and oxygen from entering the OLED of the OLED substrate from the flexible backplate 11, and the alkali metal barrier layer 115 is used for preventing migration of metal ions in the OLED substrate. The water oxygen barrier layer 113 and the alkali metal barrier layer 115 can be usually made of a silicon oxide material or a silicon nitride material.

In order to facilitate the manufacture and improve the production efficiency of the OLED substrate, the metal wiring 2 and the flatness adjustment layer 3 can be formed by using one and the same mask plate, and for the specific manufacturing method thereof, the manufacturing method for an OLED substrate provided in the embodiments of the present disclosure can be referred to, which will not be detailed herein for simplicity.

The flatness adjustment layer 3 is used for adjusting the flatness of the plane in which the metal wiring 2 is located, and it can be made of the same material as the planarization layer 4, e.g., polyethylene terephthalate (PET) or the like. The flatness adjustment layer 3 can be formed on all or part of the surface of the base substrate 1 not covered by the metal wiring 2, which can be specifically arranged upon the adjustment need of the flatness of the plane in which the metal wiring 2 is located and will not be limited herein.

Exemplarily, continuously referring to FIG. 2, the OLED substrate provided in this embodiment further comprises a pixel defining layer 6 formed on the surface of the planarization layer 4 facing away from the base substrate 1, and a spacer 7 is usually provided on a surface of the pixel defining layer 6 facing away from the planarization layer 4, and a pixel hole A is usually provided in a region of the pixel defining layer 6 corresponding to the OLED anode 5, and an OLED light emitting unit of the OLED substrate is usually provided within the pixel hole A. An orthogonal projection of the flatness adjustment layer 3 on the base substrate 1 at least covers that of the pixel hole A on the base substrate 1. In a region of the base substrate 1 to which the pixel hole A is orthogonally projected, the surface of the flatness adjustment layer 3 facing away from the base substrate 1 is at the same height level as the surface of the metal wiring 2 facing away from the base substrate 1 in this region. In the OLED substrate provided in this embodiment, a flatness adjustment layer 3 is at least formed in a region of the orthogonal projection of the pixel hole A on the base substrate 1 and thus can be used for effectively adjusting the flatness of the plane in which the metal wiring 2 at the bottom of the pixel hole A is located, thereby ensuring the flatness at the bottom of each pixel hole A of the OLED substrate, and in turn effectively improving the OLED color cast of the OLED display device in which the OLED substrate is located and ensuring the display effect of the OLED device.

The embodiments of the present disclosure further provide a manufacturing method for an OLED substrate, which is used for manufacturing the OLED substrate provided in the above embodiments.

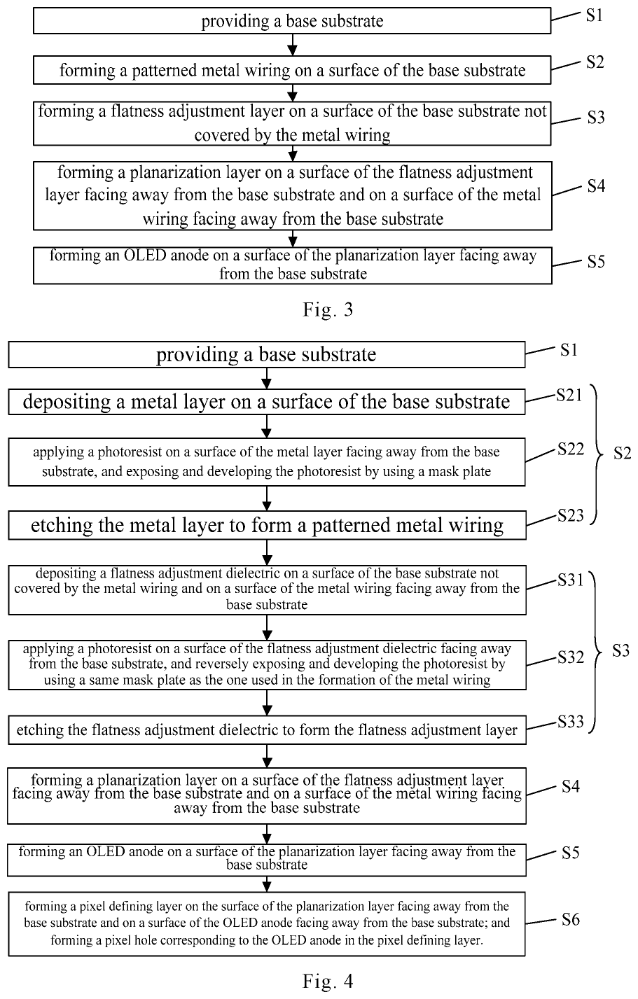

Referring to FIG. 3, the manufacturing method for an OLED substrate comprises:

Step S1, providing a base substrate.

The base substrate usually comprises a flexible backplate, and a buffer layer, an active layer, a gate insulating layer, a gate and an interlayer dielectric layer sequentially formed in a stack on the flexible backplate. Of course, if a further metal electrode such as a Ga electrode and/or a Te₂ electrode is formed between the gate and the interlayer dielectric layer, a second gate insulating layer may be further formed on a surface of the gate facing away from the first gate insulating layer, with the metal electrode such as a Ga electrode and/or a Te₂ electrode being formed on a surface of the second gate insulating layer facing away from the gate, and the interlayer dielectric layer covering the metal electrode such as a Ga electrode and/or a Te₂ electrode and the second gate insulating layer.

Step S2, forming a patterned metal wiring on a surface of the base substrate.

When the base substrate has the above structure, the metal wiring is usually formed on a surface of the interlayer dielectric layer facing away from the gate.

Step S3, forming a flatness adjustment layer on a surface of the base substrate not covered by the metal wiring.

The flatness adjustment layer is used for adjusting the flatness of the plane in which the metal wiring is located, and can be formed on all or part of the surface of the base substrate not covered by the metal wiring, i.e. on all or part of the surface of the interlayer dielectric layer not covered by the metal wiring, which can be specifically arranged upon the adjustment need of the flatness of the plane in which the metal wiring is located.

Step S4, forming a planarization layer on a surface of the flatness adjustment layer facing away from the base substrate and on a surface of the metal wiring facing away from the base substrate.

Step S5, forming an OLED anode on a surface of the planarization layer facing away from the base substrate.

The manufacturing method for an OLED substrate provided in the embodiments of the present disclosure can achieve the same beneficial effects as the OLED substrate provided in the above embodiments, which will not be repeated for simplicity.

In order to facilitate the manufacture and improve the production efficiency of the OLED substrate, the metal wiring and the flatness adjustment layer can be formed by using one and the same mask plate.

Exemplarily, referring to FIG. 4, in step S2, the step of forming a patterned metal wiring on a surface of the base substrate comprises:

Step S21, depositing a metal layer on a surface of the base substrate.

Step S22, applying a photoresist on a surface of the metal layer facing away from the base substrate, and exposing and developing the photoresist by using a mask plate.

Step S23, etching the metal layer to form a patterned metal wiring.

Continuously referring to FIG. 4, in step S3, the step of forming a flatness adjustment layer on a surface of the base substrate not covered by the metal wiring comprises:

Step S31, depositing a flatness adjustment dielectric on a surface of the base substrate not covered by the metal wiring and on a surface of the metal wiring facing away from the base substrate.

The flatness adjustment dielectric can be made of the same material as the planarization layer, and generally fabricated by using a transmissive resin such as polyethylene terephthalate (PET).

Step S32, applying a photoresist on a surface of the flatness adjustment dielectric facing away from the base substrate, and reversely exposing and developing the photoresist by using a same mask plate as the one used in the formation of the metal wiring.

Step S33, etching the flatness adjustment dielectric to form the flatness adjustment layer.

Continuously referring to FIG. 4, the manufacturing method for an OLED substrate provided in an embodiment of the present disclosure further comprises:

Step S6, forming a pixel defining layer on the surface of the planarization layer facing away from the base substrate and on a surface of the OLED anode facing away from the base substrate; and forming a pixel hole corresponding to the OLED anode in the pixel defining layer.

An orthogonal projection of the flatness adjustment layer on the base substrate at least covers that of the pixel hole on the base substrate. In a region of the base substrate to which the pixel hole is orthogonally projected, the surface of the flatness adjustment layer facing away from the base substrate is at the same height level as the surface of the metal wiring facing away from the base substrate in this region.

According to the manufacturing method for an OLED substrate provided in the embodiments of the present disclosure, a flatness adjustment layer is at least formed in a region of the orthogonal projection of the pixel hole on the base substrate and thus can be used for effectively adjusting the flatness of the plane in which the metal wiring at the bottom of the pixel hole is located, thereby ensuring the flatness at the bottom of each pixel hole of the OLED substrate, and in turn effectively improving the OLED color cast of the OLED display device in which the OLED substrate is located and ensuring the display effect of the OLED device.

The embodiments of the present disclosure further provide a display device, the display device comprising the OLED substrate provided in the above embodiments. The OLED substrate in the display device has the same advantages as the OLED substrate in the above embodiments, which will not be repeated for simplicity.

The display device provided in the above embodiments can be any product or component having a display function, such as a cell phone, a tablet computer, a television, a display, a notebook computer, a digital photo frame or a navigator.

What is mentioned above is only specific embodiments of the present disclosure, but the protection scope of the present disclosure should not be limited thereto. Any variation or substitution easily conceivable within the technical disclosure of the present disclosure for a skilled person who is familiar with this art shall fall within the protection scope of the present disclosure. Therefore, the protection scope of the present disclosure should be subject to the protection scope of the appended claims.

1. An OLED substrate, comprising:
a base substrate;
a patterned metal wiring on a surface of the base substrate;
a flatness adjustment layer on a surface of the base substrate not overlapped by the patterned metal wiring;
a planarization layer on a surface of the flatness adjustment layer away from the base substrate and on a surface of the patterned metal wiring away from the base substrate; and
an OLED anode on a surface of the planarization layer away from the base substrate.

2. The OLED substrate according to claim 1, wherein the patterned metal wiring and the flatness adjustment layer are formed by a same mask plate respectively.

3. The OLED substrate according to claim 1, further comprising:
a pixel defining layer on the surface of the planarization layer away from the base substrate,
wherein a pixel hole is in a region of the pixel defining layer corresponding to the OLED anode, and
wherein an orthogonal projection of the flatness adjustment layer on the base substrate at least overlaps an orthogonal projection of the pixel hole on the base substrate.

4. The OLED substrate according to claim 3, wherein in a region of the base substrate to which the pixel hole is orthogonally projected, the surface of the flatness adjustment layer away from the base substrate is at a same height level as the surface of the patterned metal wiring away from the base substrate in the region.

5. The OLED substrate according to claim 1,
wherein the base substrate comprises a flexible backplate, a buffer layer, an active layer, a gate insulating layer, a gate and an interlayer dielectric layer sequentially stacked on the flexible backplate, and
wherein the patterned metal wiring is on a surface of the interlayer dielectric layer away from the gate.

6. The OLED substrate according to claim 5,
wherein a first part of the patterned metal wiring is electrically connected to the active layer to form a source and a drain of a thin film transistor,
wherein the OLED anode is electrically connected to the drain of the thin film transistor, and
wherein a second part of the patterned metal wiring is electrically connected to the gate to form a signal line of a compensation circuit.

7. A manufacturing method for an OLED substrate, comprising:
providing a base substrate;
forming a patterned metal wiring on a surface of the base substrate;
forming a flatness adjustment layer on a surface of the base substrate not overlapped by the patterned metal wiring;
forming a planarization layer on a surface of the flatness adjustment layer away from the base substrate and on a surface of the patterned metal wiring away from the base substrate; and
forming an OLED anode on a surface of the planarization layer away from the base substrate.

8. The manufacturing method for the OLED substrate according to claim 7,
wherein the forming the patterned metal wiring on a surface of the base substrate comprises:
depositing a metal layer on a surface of the base substrate;
applying a photoresist on a surface of the metal layer away from the base substrate, and exposing and developing the photoresist by using a mask plate; and
etching the metal layer to form the patterned metal wiring, and
wherein the forming a flatness adjustment layer on a surface of the base substrate not overlapped by the patterned metal wiring comprises:
depositing a flatness adjustment dielectric on a surface of the base substrate not overlapped by the patterned metal wiring and on a surface of the patterned metal wiring away from the base substrate;
applying a photoresist on a surface of the flatness adjustment dielectric away from the base substrate, and reversely exposing and developing the photoresist by using a same mask plate as the one used in the forming the patterned metal wiring; and
etching the flatness adjustment dielectric to form the flatness adjustment layer.

9. The manufacturing method for the OLED substrate according to claim 7, further comprising:
forming a pixel defining layer on the surface of the planarization layer away from the base substrate and on the surface of the OLED anode away from the base substrate; and
forming a pixel hole corresponding to the OLED anode in the pixel defining layer,
wherein an orthogonal projection of the flatness adjustment layer on the base substrate at least overlaps an orthogonal projection of the pixel hole on the base substrate.

10. A display device, comprising the OLED substrate according to claim 1.

11. A display device, comprising the OLED substrate according to claim 2.

12. A display device, comprising the OLED substrate according to claim 3.

13. A display device, comprising the OLED substrate according to claim 4.

14. A display device, comprising the OLED substrate according to claim 5.

15. A display device, comprising the OLED substrate according to claim 6.

16. The manufacturing method for the OLED substrate according to claim 8, further comprising:
forming a pixel defining layer on the surface of the planarization layer away from the base substrate and on the surface of the OLED anode away from the base substrate; and
forming a pixel hole corresponding to the OLED anode in the pixel defining layer,
wherein an orthogonal projection of the flatness adjustment layer on the base substrate at least overlaps an orthogonal projection of the pixel hole on the base substrate.
